(19) United States
(12) Patent Application Publication
(10) Pub. No.: US 2025/0015049 A1
(43) Pub. Date: Jan. 9, 2025

(54) SEMICONDUCTOR PACKAGE AND MANUFACTURING METHOD FOR THE SAME

(71) Applicant: SAMSUNG ELECTRONICS CO., LTD., Suwon-si (KR)

(72) Inventors: Hwanjoo Park, Suwon-si (KR); Sunggu Kang, Suwon-si (KR); Jae Choon Kim, Suwon-si (KR); Taehwan Kim, Suwon-si (KR)

(21) Appl. No.: 18/412,447

(22) Filed: Jan. 12, 2024

(30) Foreign Application Priority Data
Jul. 4, 2023 (KR) 10-2023-0086432

(51) Int. Cl. H01L 25/065; H01L 21/56; H01L 21/768; H01L 23/00; H01L 23/31; H01L 23/48; H01L 23/538; H10B 80/00

(52) U.S. Cl. CPC H01L 25/0657; H01L 21/56; H01L 21/76898; H01L 23/3121; H01L 23/481; H01L 23/5383; H01L 24/16; H01L 24/17; H10B 80/00; H01L 2224/16227; H01L 2224/17181; H01L 2224/81; H01L 2225/06568

(57) ABSTRACT

A semiconductor package includes a redistribution line structure that has a redistribution line layer. A first semiconductor chip is disposed above the redistribution line structure and includes a first region with a first thickness and a second region with a second thickness that is less than the first thickness. A sub-semiconductor package includes a second semiconductor chip and is disposed above the second region of the first semiconductor chip. A silicon through via penetrates the second region of the first semiconductor chip and electrically connects the sub-semiconductor package with the redistribution line structure. A sealant seals at least a portion of each of the first semiconductor chip and the sub-semiconductor package. The sub-semiconductor package is disposed within the second region of the first semiconductor chip.

### CROSS-REFERENCE TO RELATED APPLICATION

This application claims priority under 35 U.S.C. § 119 to Korean Patent Application No. 10-2023-0086432, filed in the Korean Intellectual Property Office on Jul. 4, 2023, the entire contents of which are herein incorporated by reference.

### TECHNICAL FIELD

The present disclosure relates to semiconductors and, more specifically, to a semiconductor package and a manufacturing method for the same.

### DISCUSSION OF THE RELATED ART

As semiconductors develop, there is a need to increase integration density so that more circuit elements, both active and passive, may be fit within a given space. As the ability to fit more and more circuit elements into a single chip may be limited, advanced packaging techniques have been developed to fit multiple chips within a single package. Another approach is to combine multiple semiconductor packages, thereby achieving high integration density. One example of such a packaging technique is the package-on-package (POP) structure in which a second semiconductor package is stacked at an upper portion of a first semiconductor package.

A conventional package-on-package structure may be formed by mounting a semiconductor chip on a front side redistribution line (FRDL) structure, molding the semiconductor chip to form a lower semiconductor package, and disposing an upper semiconductor package separately formed from the lower semiconductor package on the lower semiconductor package.

In the package-on-package structure, a space for stacking an upper package is secured, and there may be a problem in which a thickness of a lower package is limited due to this. In addition, there is a connection structure such as a metal post, a through mold via (TMV), or the like for signal transfer of the upper package within the lower package. As a result, there may be a problem in which an area that the semiconductor chip may occupy within the lower semiconductor package is also limited. In addition, since the upper package is electrically connected to the front side redistribution line structure via the connection structure or the like of the lower package, there may be a problem in which a signal transfer path of the upper package becomes longer.

In addition, the upper package is placed on the lower package, a molding material such as an epoxy molding compound (EMC) or the like is used. This molding material may be in a form of an over-mold that covers an upper surface of the semiconductor chip even within the lower package itself, and in a case of a semiconductor package including a back side redistribution line structure, additional components are interposed between the upper and lower packages. These may prevent heat generated in the lower package from being efficiently dissipated outside the package.

### SUMMARY

A semiconductor package includes a redistribution line structure having a redistribution line layer. A first semiconductor chip is disposed above the redistribution line structure and includes a first region with a first thickness and a second region with a second thickness that is less than the first thickness. A sub-semiconductor package includes a second semiconductor chip disposed above the second region of the first semiconductor chip. A silicon through via penetrates the second region of the first semiconductor chip and electrically connects the sub-semiconductor package with the redistribution line structure. A sealant seals at least a portion of each of the first semiconductor chip and the sub-semiconductor package. The sub-semiconductor package is disposed within the second region of the first semiconductor chip.

The first semiconductor chip and the sub-semiconductor package may be exposed to one surface of the sealant.

On the one surface of the sealant, one surfaces of the first semiconductor chip, the sub-semiconductor package, and the sealant may be coplanar with one another.

The thickness of the second region of the first semiconductor chip may be within a range of 50 μm to 400 μm.

The thickness of the first region of the first semiconductor chip may be within a range of 500 μm to 800 μm.

When a direction perpendicular to a direction from the first region of the first semiconductor chip to the second region of the first semiconductor chip on a plane (e.g., in a plan view) is a width direction, a width of the first region of the first semiconductor chip and a width of the second region of the first semiconductor chip may be substantially equal to one another.

At least a portion of the second region may be surrounded by the first region, and the first region and the second region may have a plurality of boundary surfaces.

A length of the first semiconductor chip may be within a range of 11 mm to 20 mm.

The first semiconductor chip may include a logic chip, and the second semiconductor chip may include a memory chip.

A semiconductor package includes a redistribution line structure that has a redistribution line layer. A first semiconductor chip is disposed above the redistribution line structure and includes a body and a connecting pad electrically connected to the redistribution line structure. A sub-semiconductor package is disposed above the first semiconductor chip and includes a substrate having a wiring layer, a second semiconductor chip disposed above the substrate, and a first sealant sealing at least a portion of the second semiconductor chip. A silicon through via penetrates the first semiconductor chip and electrically connects the sub-semiconductor package with the redistribution line structure. A second sealant seals at least a portion of each of the first semiconductor chip and the sub-semiconductor package. The first semiconductor chip includes a first region with a first thickness and a second region with a second thickness that is less than the first thickness. The first region of the first semiconductor chip is exposed to one surface of the second sealant, the sub-semiconductor package is disposed above the second region of the first semiconductor chip, and the silicon through via penetrates the second region of the first semiconductor chip.

The sub-semiconductor package may be exposed to the one surface of the second sealant to which the first semiconductor chip is exposed.

The semiconductor package may further include a first via pad and a second via pad that are respectively disposed on both surfaces of the body of the first semiconductor chip and are connected to each other by the silicon through via.

The semiconductor package may further include a bump disposed above the first semiconductor chip that electrically connects the first via pad to the substrate.

The semiconductor package may further include a bump disposed on the redistribution line structure that electrically connects at least one of the connecting pad and the second via pad to the redistribution line structure.

The first via pad may directly contact at least one wiring pattern included in the wiring layer of the substrate.

At least one of the connecting pad and the second via pad may directly contact at least one redistribution line pattern included in the redistribution line layer.

A manufacturing method for the semiconductor package includes preparing a redistribution line structure including a redistribution line layer. A first semiconductor chip including a first region with a first thickness and a second region with a second thickness that is less than the first thickness is prepared. The first semiconductor chip is disposed above the redistribution line structure. A silicon through via penetrating the second region of the first semiconductor chip is formed. A sub-semiconductor package is disposed above the second region of the first semiconductor chip and electrically connects the sub-semiconductor package with the silicon through via. The first semiconductor chip and the sub-semiconductor package are sealed with a sealant and the sealant is grinded.

The grinding of the sealant may expose the first region of the first semiconductor chip.

In the preparing of the first semiconductor chip, the second region of the first semiconductor chip may have a smaller thickness than that of the first region of the first semiconductor chip as a result of grinding or wet etching.

The manufacturing method may further include forming a via pad on one surface of a body of the first semiconductor chip. The forming of the silicon through via may include forming a through hole penetrating the body to expose the via pad and filling the through hole with a metal.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a schematic cross-sectional view of a semiconductor package according to an embodiment of the present disclosure.

FIG. 2 is a schematic cross-sectional view of a semiconductor package according to an embodiment of the present disclosure.

FIG. 3 is a schematic cross-sectional view of a semiconductor package according to an embodiment of the present disclosure.

FIGS. 4A to 4D are perspective views showing an example shape of a semiconductor chip of the present disclosure.

FIGS. 5A to 5G are schematic manufacturing process views of the semiconductor package according to an embodiment of the present disclosure.

### DETAILED DESCRIPTION OF THE EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

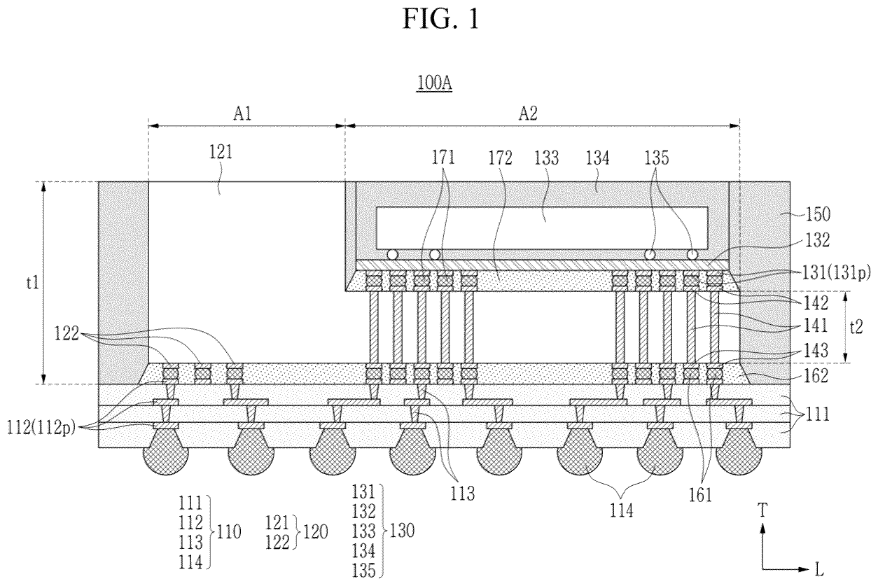

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like. In the drawings, a length direction (L), a width direction (W), and a thickness direction (T) are shown as facing only one direction, but a direction opposite to a direction indicated in the drawings may also be referred to as the same direction. For example, the thickness direction (T) includes both a right direction and a left direction with respect to FIG. 1.

Throughout the specification, when a part is “connected” to another part, it includes not only a case where the part is “directly connected” but also a case where the part is “indirectly connected” with another part in between. In a similar sense, this includes being “physically connected” as well as being “electrically connected”. In addition, unless explicitly described to the contrary, the word “comprise” and variations such as “comprises” or “comprising” will be understood to imply the inclusion of stated elements but not the exclusion of any other elements.

Throughout the specification, it will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

In addition, throughout the specification, sequential numbers such as 1st and 2nd are used to distinguish a certain component from another component that is the same or similar to the same, and are not necessarily intended to refer to a specific component. Accordingly, a component referred to as a first component in a specific portion of the specification may be referred to as a second component in another portion of the specification.

Additionally, throughout the specification, a singular reference to a component includes references to a plurality of these components, unless specifically stated to the contrary. For example, “a wire layer” may be used to mean not only one wire layer but also a plurality of wire layers such as two, three, or more wire layers.

In addition, throughout the specification, references to one surface and the other surface are intended to distinguish different surfaces from each other, and are not necessarily intended to limit it to a specific surface. Accordingly, a surface referred to as one surface in a specific portion of the specification may be referred to as the other surface in another portion of the specification.

Hereinafter, a semiconductor package according to an embodiment will be described with reference to the drawings.

FIG. 1 is a schematic cross-sectional view of a semiconductor package according to an embodiment of the present disclosure.

Referring to FIG. 1, the semiconductor package 100A, according to an embodiment of the present disclosure, may include a redistribution line structure (or a rewiring structure) 110, a first semiconductor chip 120, a sub-semiconductor package 130, a silicon through via 141, and a sealant (or an encapsulant) 150.

The redistribution line structure 110 may include an insulating layer 111, a redistribution line layer 112, and a via 113, and may further include a connection structure 114. The number of each of the insulating layer 111, the redistribution line layer 112, the via 113, and/or the connection structure 114 is not necessarily limited to that shown in the drawings, and depending on a design, the redistribution line structure 110 may include a single or plurality of insulating layers 111, redistribution line layers 112, vias 113, and/or connection structures 114 more or less than those shown in the drawings.

The insulating layer 111 may include a photo-imageable dielectric (PID). As an embodiment, the photo-imageable dielectric (PID) may include a polyimide-based photosensitive polymer, a novolac-based photosensitive polymer, polybenzoxazole, a silicone-based polymer, an acrylate-based polymer, or an epoxy-based polymer. In an embodiment, the insulating layer 111 may be formed of an inorganic dielectric material such as silicon nitride, silicon oxide, or the like. Depending on a formation material of the insulating layer 111, a boundary may or might not exist between the plurality of insulating layers 111. When the redistribution line structure 110 includes the plurality of insulating layers 111, formation materials of the plurality of insulating layers 111 may be the same or different from each other.

The redistribution line layer 112 may be disposed on the insulating layer 111 to be buried in the insulating layer 111 disposed in another layer. The redistribution line layer 112 disposed at a layer closest to the first semiconductor chip 120 may be disposed on a surface facing the first semiconductor chip 120 of the insulating layer 111. This structure may be advantageous in terms of yield because it is easy to apply the first semiconductor chip 120 above or on the redistribution line structure 110 in a chip-last method. The redistribution line layer 112 may include at least one redistribution line pattern 112p. Particularly, the redistribution line pattern 112p included in an outermost redistribution line layer 112 may serve as a connecting pad for electrically connecting the semiconductor package 100A with another structure. The insulating layer 111 disposed at an outermost side may have an opening for exposing at least a portion of the redistribution line pattern 112p that serves as the connecting pad. Additionally, the redistribution line pattern 112p included in the redistribution line layer 112 facing the first semiconductor chip 120 may serve as a connecting pad for electrically connecting the redistribution line structure 110 with the first semiconductor chip 120. Formation materials of the redistribution line layer 112 and the redistribution line pattern 112p may include aluminum (Al), copper (Cu), gold (Au), silver (Ag), platinum (Pt), tin (Sn), chromium (Cr), palladium (Pd), lead (Pb), titanium (Ti), or an alloy thereof, but the present disclosure is not necessarily limited thereto.

The via 113 may penetrate the insulating layer 111 to connect the redistribution line layers 112 disposed in different layers to each other. The via 113 may have a tapered shape whose diameter narrows in a direction from one surface to the other surface. For example, as shown in the drawings, the via 113 may have the tapered shape whose diameter becomes narrower as it moves away from the first semiconductor chip 120. However, the via 113 may have a tapered shape whose diameter becomes wider as it moves away from the first semiconductor chip 120, or may have a circular cylinder shape. A formation material of the via 113 may be the same as a formation material of the redistribution line pattern 112p, and the via 113 may be integrally formed with the redistribution line pattern 112p so that there is no boundary between the via 113 and the redistribution line pattern 112p. For example, the redistribution line pattern 112p and the via 113 may be integrally formed through a method in which a through hole is formed at the insulating layer 111, a seed layer is formed to extend from a surface of a wall of the through hole to one surface of the insulating layer 111, and then an electrolytic plating layer is formed on the seed layer to fill the through hole.

The connection structure 114 is a configuration for connecting the semiconductor package 100A with another structure such as a printed circuit board or the like. The connection structure 114 may be disposed on the redistribution line structure 110, and for example, may be disposed on the redistribution line pattern 112p exposed through an opening of the insulating layer 111 disposed at an outermost side of the redistribution line structure 110. A formation material of the connection structure 114 may include copper (Cu), palladium (Pd), bismuth (Bi), antimony (Sb), tin (Sn), silver (Ag), or an alloy thereof such as a tin-silver (SnAg) alloy. For example, the connection structure 114 may be a solder ball.

The first semiconductor chip 120 may be disposed above or on the redistribution line structure 110, and may include a body 121 and a connecting pad 122 electrically connected to the redistribution line structure 110. Additionally, the first semiconductor chip 120 may include a first region A1 having a first thickness t1 and a second region A2 having a second thickness t2 that is less than the first thickness t1.

On one surface of the first semiconductor chip 120, the first region A1 and the second region A2 may have a step difference and the first region A1 may be disposed at a higher level than the second region A2. For example, one surface of the first semiconductor chip 120 may have a step shape. The first region A1 and the second region A2 of the first semiconductor chip 120 may be coplanar on the other surface of the first semiconductor chip 120 facing the redistribution line structure 110.

The second region A2 of the first semiconductor chip 120 may be formed by removing a portion of a region of a semiconductor chip in a thickness direction of the semiconductor chip using a physical or chemical method. For example, the second region A2 of the first semiconductor chip 120 may be formed by preparing the semiconductor chip with a first thickness t1 and removing a portion of the semiconductor chip in the thickness direction from a region corresponding to the second region A2. The physical or chemical method may be grinding or wet etching.

The first thickness t1 of the first region A1 of the first semiconductor chip 120 may be within a range of from 500 μm to 800 μm (inclusive). For example, the first thickness t1 may be 500 μm, 550 μm, 600 μm, 650 μm, 700 μm, or 750 μm or more. Additionally, the first thickness t1 may be less than or equal to 800 μm, 750 μm, 700 μm, 650 μm, 600 μm, or 550 μm. In the case of the semiconductor package 100A, according to the present disclosure, the sub-semiconductor package 130 is disposed at the second region A2 of the first semiconductor chip 120, so that no separate space is required to dispose the semiconductor package on an upper portion of a lower semiconductor chip. Accordingly, the first region A1 of the first semiconductor chip 120 where the sub-semiconductor package 130 is not disposed may have a relatively great thickness. However, in order to reduce a thickness of the semiconductor package, the first region A1 of the first semiconductor chip 120 may have a thickness of 800 μm or less.

The second thickness t2 of the second region A2 of the first semiconductor chip 120 may be within a range of 50 μm to 400 μm (inclusive). For example, the second thickness t2 may be 50 μm, 100 μm, 150 μm, 200 μm, 250 μm, 300 μm, or 350 μm or more. Additionally, the second thickness t2 may be to 400 μm, 350 μm, 300 μm, 250 μm, 200 μm, 150 μm, or 100 μm or less. The second region A2 of the first semiconductor chip 120 may have a relatively small thickness through grinding or the like. However, the second region A2 of the first semiconductor chip 120 may have the above-mentioned minimum thickness due to a processing limitation and a handling problem.

A length of the first semiconductor chip 120 in the length direction (L) may be with a range of 11 mm to 20 mm (inclusive), and for example, may be within a range of 18 mm to 19 mm (inclusive). In the present specification, the length refers to a length measured in the longitudinal direction (L) from the first region A1 to the second region A2 with reference to FIG. 1. For example, the length of the first semiconductor chip 120 in the length direction (L) may be 11 mm, 12 mm, 13 mm, 14 mm, 15 mm, 16 mm, 17 mm, 18 mm, or 19 mm or more. Additionally, the length of the first semiconductor chip 120 in the length direction (L) may be 20 mm, 19 mm, 18 mm, 17 mm, 16 mm, or 15 mm or less.

Additionally, a width of the first semiconductor chip 120 in the width direction (W) may be within a range of 9 mm to 14 (inclusive), and for example, may be within a range of 11 mm to 12 mm (inclusive). In the present specification, the width refers to a length measured in the width direction (W) perpendicular to the longitudinal direction (L) on a plane (e.g., in a plan view). For example, the width of the first semiconductor chip 120 in the width direction (W) may be 9 mm, 9.5 mm, 10 mm, 10.5 mm, 11 mm, 11.5 mm, 12 mm, 12.5 mm, 13 mm, or 13.5 mm or more. Additionally, the width of the first semiconductor chip 120 in the width direction (W) may be 14 mm, 13.5 mm, 13 mm, 12.5 mm, 12 mm, 11.5 mm, 11 mm, 10.5 mm, 10 mm, or 9.5 mm or less.

In the case of the semiconductor package 100A, according to the present disclosure, the sub-semiconductor package 130 and the redistribution line structure 110 are connected through the silicon through via 141 that penetrates the first semiconductor chip 120, so that a separate space for the connection structure connecting the sub-semiconductor package 130 and the redistribution line structure 110 is also not required. Therefore, the first semiconductor chip 120 may have a relatively great length and a relatively great width. However, in order to miniaturize the semiconductor package 100A, the first semiconductor chip 120 may have a limited length and width within a predetermined range.

The body 121 may include a silicon substrate, an integrated circuit layer formed on the silicon substrate, and an interlayer insulating layer covering the integrated circuit layer.

The connecting pad 122 may electrically connect the first semiconductor chip 120 to the redistribution line structure 110, and may be formed of a metal such as aluminum (Al), copper (Cu), or the like. In the drawings, the connecting pad 122 may be shown as being disposed only at the first region A1 of the first semiconductor chip 120, but depending on a design, the connecting pad 122 may be disposed in another location, such as at the second region A2.

The first semiconductor chip 120 may include a logic chip such as a central processing unit (CPU), a graphics processing unit (GPU), an application processor (AP), or the like.

The sub-semiconductor package 130 may be disposed on the second region A2 of the first semiconductor chip 120. For example, the sub-semiconductor package 130 may be disposed on the second region A2 of the first semiconductor chip 120 and within the second region A2. Being disposed within the second region A2 of the first semiconductor chip 120 means that there is no configuration outside the second region A2 on a plane (e.g., in a plan view). However, due to an error in a process or the like, all or some of some components of the sub-semiconductor package 130 may be disposed outside the second region A2 of the first semiconductor chip 120. However, an object intended by the present disclosure may be achieved if the sub-semiconductor package 130 is not disposed above or on the first region A1 of the first semiconductor chip 120.

The sub-semiconductor package 130 may include a substrate 132 including a wiring layer 131, a second semiconductor chip 133 disposed above the substrate 132, and a sealant 134 that seals at least a portion of the second semiconductor chip 133, and the sub-semiconductor package 130 may further include a bump 135 connecting the substrate 132 and the second semiconductor chip 133. For example, the sub-semiconductor package 130 may be a flip-chip semiconductor package, a fan-out wafer level package (FOWLP), or a fan-out panel level package (FOPLP), or the like. For convenience of description below, the sealant 134 included in the sub-semiconductor package 130 will be referred to as a first sealant 134 to distinguish the sealant 134 from the sealant 150 that seals the first semiconductor chip 120 and the sub-semiconductor package 130 that will be described later.

The wiring layer 131 may include at least one wiring pattern 131p. Although only one wiring layer 131 disposed at an outermost side of the substrate 132 is shown in the drawings, a plurality of wiring layers 131 may be included in the substrate 132. For example, the wiring pattern 131p included in the wiring layer 131 disposed at the outermost side may serve as a connecting pad for electrically connecting the sub-semiconductor package 130 with the first semiconductor chip 120. Formation materials of the wiring layer 131 and the wiring pattern 131p may include aluminum (Al), copper (Cu), gold (Au), silver (Ag), platinum (Pt), tin (Sn), chromium (Cr), palladium (Pd), lead (Pb), titanium (Ti), or an alloy thereof, but the present disclosure is not necessarily limited thereto.

The substrate 132 may include constituent elements (e.g., such as an insulating layer, a via, and the like) generally included in the substrate in addition to the wiring layer 131. The number of insulating layers and vias included in the substrate 132 is not necessarily particularly limited, and the substrate 132 may include a singular or plurality of insulating layers and/or vias.

The second semiconductor chip 133 may include a memory chip such as a dynamic random access memory (DRAM). Like the first semiconductor chip 120, the second semiconductor chip 133 may also include a body, a connecting pad, and the like.

The first sealant 134 may protect the second semiconductor chip 133, and may be formed of a thermosetting resin such as an epoxy resin, an epoxy molding compound (EMC), or the like. A process of molding the second semiconductor chip 133 with the first sealant 134 may be performed by compression molding or transfer molding.

The bump 135 may electrically connect the second semiconductor chip 133 to the substrate 132. The bump 135 may be disposed between the second semiconductor chip 133 and the substrate 132 and may be covered with an underfill. However, depending on a type of the semiconductor package, the sub-semiconductor package 130 might not include the bump 135 and/or the underfill.

A conductive material may be used as a formation material for the bump 135, and for example, a formation material of the bump 135 may include copper (Cu), palladium (Pd), bismuth (Bi), antimony (Sb), tin (Sn), silver (Ag), or an alloy thereof such as a tin-silver (SnAg) alloy.

The silicon through via 141 may penetrate the second region A2 of the first semiconductor chip 120, and may electrically connect the sub-semiconductor package 130 with the redistribution line structure 110. For example, the silicon through via 141 may penetrate the body 121 of the first semiconductor chip 120 in the second region A2 of the first semiconductor chip 120.

For example, the silicon through via 141 may be formed through a method in which a through hole penetrating the first semiconductor chip 120 (for example, the body 121) is formed, a seed layer is formed at a surface of a wall of the through hole, and then an electrolytic plating layer is formed on the seed layer to fill the through hole.

A formation material of the silicon through via 141 may include aluminum (Al), copper (Cu), gold (Au), silver (Ag), platinum (Pt), tin (Sn), chromium (Cr), palladium (Pd), lead (Pb), titanium (Ti), or an alloy thereof, but the present disclosure is not necessarily limited thereto.

The semiconductor package 100A may further include a first via pad 142 and a second via pad 143 that are respectively disposed on both surfaces of the first semiconductor chip 120 (for example, the body 121 of the first semiconductor chip 120) and are connected to each other through the silicon through via 141. The first via pad 142 and the second via pad 143 may face each other. Based on the drawings, the via pad facing the sub-semiconductor package 130 is described as the first via pad 142, and the via pad facing the redistribution line structure 110 is described as the second via pad 143. Accordingly, the second via pad 143 may be disposed on a surface of the body 121 of the first semiconductor chip 120 where the connecting pad 122 is disposed.

At least one of the first via pad 142 and the second via pad 143 may be integrally formed with the silicon through via 141. For example, when the silicon through via 141 is formed, the seed layer may extend from the surface of the wall of the through hole onto one surface of the body 121 of the first semiconductor chip 120 and then the electrolytic plating layer may be formed on the seed layer so that the first via pad 142 is integrally formed with the silicon through via 141.

The second sealant 150 may seal at least a portion of each of the first semiconductor chip 120 and the sub-semiconductor package 130. The second sealant 150 may protect the first semiconductor chip 120 and the sub-semiconductor package 130, and may be formed of a thermosetting resin such as an epoxy resin, an epoxy molding compound (EMC), or the like. A process of molding the first semiconductor chip 120 and the sub-semiconductor package 130 with the second sealant 150 may be performed by compression molding or transfer molding.

At least one of the first semiconductor chip 120 and the sub-semiconductor package 130 may be exposed to one surface of the second sealant 150. In this case, a configuration of the sub-semiconductor package 130 exposed to the one surface of the second sealant 150 may be the first sealant 134.

In an embodiment, the first region A1 of the first semiconductor chip 120 may be exposed to the one surface of the second sealant 150. Through this structure, heat generated in the semiconductor package 100A may be more efficiently dissipated to the outside of the package through the exposed surface of the first semiconductor chip 120.

In an embodiment, the sub-semiconductor package 130, along with the first region A1 of the first semiconductor chip 120, may be exposed to the one surface of the second sealant 150. In this case, the second sealant 150 may be ground to expose the first semiconductor chip 120 and the sub-semiconductor package 130. Therefore, on one surface of the second sealant 150 where the first semiconductor chip 120 and the sub-semiconductor package 130 are exposed, one surfaces of the first semiconductor chip 120, the sub-semiconductor package 130, and the second sealant 150 may be coplanar. Through this structure, when another structure is attached to the semiconductor package 100A using a thermal paste or the like, adhesion between the semiconductor package 100A and the attached structure may be excellent.

However, if necessary, the first semiconductor chip 120 may be buried in the second sealant 150, and only the sub-semiconductor package 130 may be exposed to the one surface of the second sealant 150. Alternatively, both the first semiconductor chip 120 and the sub-semiconductor package 130 may be buried in the second sealant 150.

Additionally, the semiconductor package 100A may further include a first bump 161 that is disposed above or on the redistribution line structure 110 to connect at least one of the connecting pad 122 of the first semiconductor chip 120 and the second via pad 143 with the redistribution line structure 110. A conductive material may be used as a formation material for the first bump 161, and for example, a formation material of the first bump 161 may include copper (Cu), palladium (Pd), bismuth (Bi), antimony (Sb), tin (Sn), silver (Ag), or an alloy thereof such as a tin-silver (SnAg) alloy.

In this case, in order to distribute a stress applied to the first bump 161, a first underfill 162 may surround the first bump 161 between the redistribution line structure 110 and the first semiconductor chip 120. The first underfill 162 may cover a portion of a side surface of the first semiconductor chip 120. The first underfill 162 may be formed of an underfill resin such as an epoxy resin, and may include a silica filler, a flux, or the like. The first underfill 162 may be formed of the same material as that of the second sealant 150, or may be formed of a different material from that of the second sealant 150. The first underfill 162 may have a shape that widens from an upper portion thereof to a lower portion thereof, but a shape of the first underfill 162 is not necessarily limited thereto.

Additionally, the semiconductor package 100A may further include a second bump 171 that is disposed above or on the first semiconductor chip 120 to connect the first via pad 142 with the substrate 132. Like the formation material of the first bump 161, a conductive material may be used as a formation material for the second bump 171, and for example, a formation material of the second bump 171 may include copper (Cu), palladium (Pd), bismuth (Bi), antimony (Sb), tin (Sn), silver (Ag), or an alloy thereof such as a tin-silver (SnAg) alloy.

In this case, to distribute a stress applied to the second bump 171, a second underfill 172 may surround the second bump 171 between the first semiconductor chip 120 and the substrate 132. The second underfill 172 may cover a portion of a side surface of the substrate 132. The second underfill 172 may be formed of an underfill resin such as an epoxy resin, and may include a silica filler, a flux, or the like. The second underfill 172 may be formed of the same material as that of the second sealant 150, or may be formed of a different material from that of the second sealant 150. The second underfill 172 may have a shape that widens from an upper portion thereof to a lower portion thereof, but a shape of the second underfill 172 is not necessarily limited thereto.

In the case of the semiconductor package 100A, according to the present disclosure, the sub-semiconductor package 130 is disposed at the second region A2 of the first semiconductor chip 120 so that no separate space is required to dispose the semiconductor package on the upper portion of the lower semiconductor chip. In addition, the sub-semiconductor package 130 and the redistribution line structure 110 are connected through the silicon through via 141 that penetrates the first semiconductor chip 120, so that the separate space for the connection structure connecting the sub-semiconductor package 130 and the redistribution line structure 110 is also not required. Therefore, the semiconductor package 100A, according to the present disclosure, may have a large area and thickness within the package and may lessen limitation of space constraints within the semiconductor package compared with a structure in which a plurality of semiconductor chips are disposed side by side to be packaged and a typical package-on-package structure that vertically stacks a plurality of packages.

In addition, the sub-semiconductor package 130 may be connected to the redistribution line structure 110 through the silicon through via 141 that penetrates the second region A2 of the first semiconductor chip 120 having a thin thickness so that it may have a short signal path, and through this, the sub-semiconductor package 130 may have an excellent signal characteristic. Additionally, since the silicon through via 141 is not particularly required at the first region A1 of the first semiconductor chip 120, a problem in which a thickness of the semiconductor chip is limited due to a process of forming the silicon through via might not occur.

In addition, the semiconductor package 100A, according to the present disclosure, may have an increased heat-dissipation characteristic because heat generated from the sub-semiconductor package 130 may be dissipated in horizontal and vertical directions through the first semiconductor chip 120 that has high thermal conductivity. In addition, no other semiconductor package may be present above or on the first region A1 of the first semiconductor chip 120 and the first region A1 of the first semiconductor chip 120 may be exposed to one surface of the second sealant 150, so that heat generated in the semiconductor package 100A may be more efficiently dissipated to the outside of the package through the exposed surface of the first semiconductor chip 120.

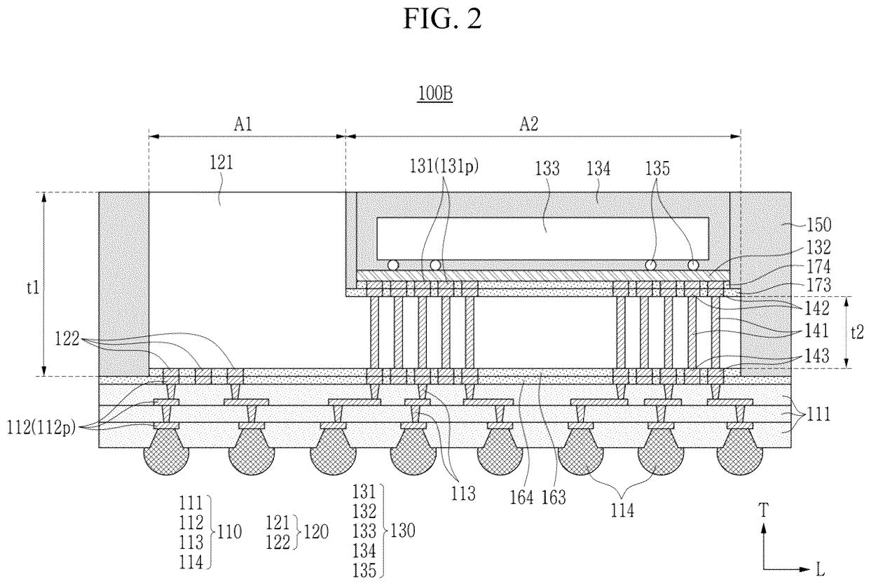

FIG. 2 is a schematic cross-sectional view of a semiconductor package according to an embodiment of the present disclosure.

Referring to FIG. 2, the semiconductor package 100B, according to an embodiment of the present disclosure, has a connection structure between the redistribution line structure 110, the first semiconductor chip 120, and the sub-semiconductor package 130 that is different from that of the semiconductor package 100A according to the embodiment of the present disclosure. When the redistribution line structure 110, the first semiconductor chip 120, and the sub-semiconductor package 130 are connected to each other by hybrid bonding, the semiconductor package 100B may have the structure shown in FIG. 2.

For example, at least one of the connecting pad 122 of the first semiconductor chip 120 and the second via pad 143 may be directly bonded to directly contact at least one redistribution line pattern 112p included in the redistribution line layer 112 by metal-metal hybrid bonding of the hybrid bonding, and a first coupling member 163 may be directly bonded to directly contact a second coupling member 164 by non-metal-non-metal hybrid bonding of the hybrid bonding. The first coupling member 163 may be disposed on one surface of the first semiconductor chip 120 at which the connecting pad 122 and the second via pad 143 are disposed, and the second coupling member 164 may be disposed on the insulating layer 111 of the redistribution line structure 110. Here, the “direct contact” may mean that no other member is present between components and thus the components are in physical contact with each other.

Similarly, in the semiconductor package 100B, according to an embodiment of the present disclosure, the first via pad 142 may be directly bonded to directly contact at least one wiring pattern 131p included in the wiring layer 131 of the substrate 132 by the metal-metal hybrid bonding, and a third coupling member 173 may be directly bonded to directly contact a fourth coupling member 174 by the non-metal-non-metal hybrid bonding. The third coupling member 173 may be disposed on the other surface of the first semiconductor chip 120 where the sub-semiconductor package 130 is disposed in the second region A2 of the first semiconductor chip 120, and the fourth coupling member 174 may be disposed on the substrate 132.

The hybrid bonding means bonding two devices by fusing the same materials of the two devices using bonding properties of the same materials. Here, the hybrid bonding means bonding the two devices by two different types of bonding (for example, bonding the two devices with a first type of metal-to-metal bonding and a second type of non-metal-to-non-metal bonding). By the hybrid bonding, I/O with a fine pitch may be formed.

In the drawings, the redistribution line structure 110 and the first semiconductor chip 120, and the first semiconductor chip 120 and the sub-semiconductor package 130 are all connected by the hybrid bonding, but only one of the redistribution line structure 110 and the first semiconductor chip 120, and the first semiconductor chip 120 and the sub-semiconductor package 130 may be connected by the hybrid bonding. For example, the redistribution line structure 110 and the first semiconductor chip 120 may be hybrid bonded, and the first semiconductor chip 120 and the sub-semiconductor package 130 may be flip-chip bonded through bumps. Alternatively, the first semiconductor chip 120 and the sub-semiconductor package 130 may be hybrid bonded, and the redistribution line structure 110 and the first semiconductor chip 120 may be flip-chip bonded through bumps.

Since description of other configurations is the same as that specifically described in the semiconductor package 100A, according to the embodiment of the present disclosure, to the extent that an element is not described in detail with respect to this figure, it may be understood that the element is at least similar to a corresponding element that has been described elsewhere within the present disclosure.

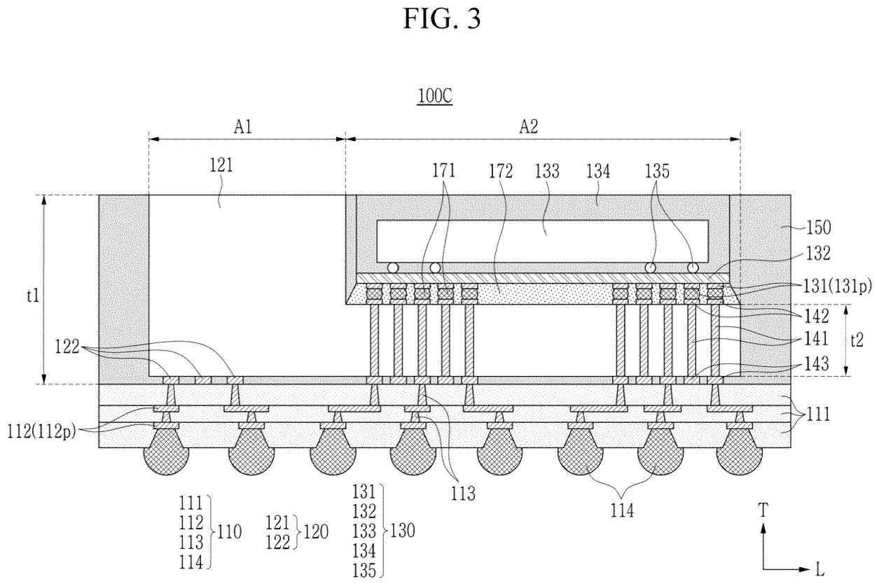

FIG. 3 is a schematic cross-sectional view of a semiconductor package according to an embodiment of the present disclosure.

Referring to FIG. 3, the semiconductor package 100C, according to an embodiment of the present disclosure, has a structure of the redistribution line structure 110 and a connection method between the redistribution line structure 110, the first semiconductor chip 120, the sub-semiconductor package 130, and the second via pad 143 that are different from those of the semiconductor package 100A, according to the embodiment of the present disclosure. In the case of applying a chip-first method in which the semiconductor chip is first disposed and the redistribution line structure is formed above or on the semiconductor chip when the redistribution line structure 110 and the first semiconductor chip 120 are connected, the semiconductor package 100C may have a structure shown in FIG. 3.

For example, in the redistribution line structure 110 of the semiconductor package 100C, the redistribution line layer 112 may be disposed on an opposite surface of a surface facing the first semiconductor chip 120 of the insulating layer 111, and the via 113 may have a tapered shape whose diameter becomes wider as it moves away from the first semiconductor chip 120.

Additionally, the redistribution line structure 110 may be directly connected to the first semiconductor chip 120 and the second via pad 143 without the first bump 161. In this case, the connecting pad 122 of the first semiconductor chip 120 and the second via pad 143 may be connected to the redistribution line layer 112 through the via 113.

Since description of other configurations is the same as that specifically described in the semiconductor package 100A according to the embodiment of the present disclosure, to the extent that an element is not described in detail with respect to this figure, it may be understood that the element is at least similar to a corresponding element that has been described elsewhere within the present disclosure.

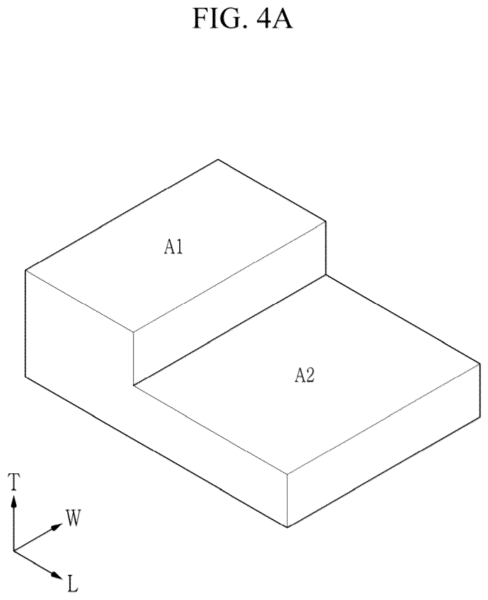

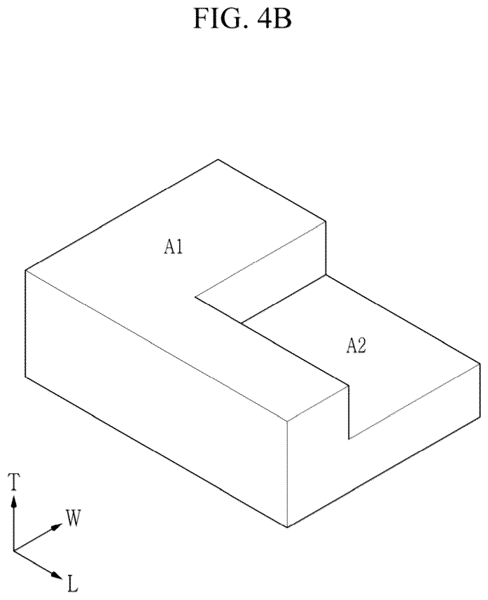

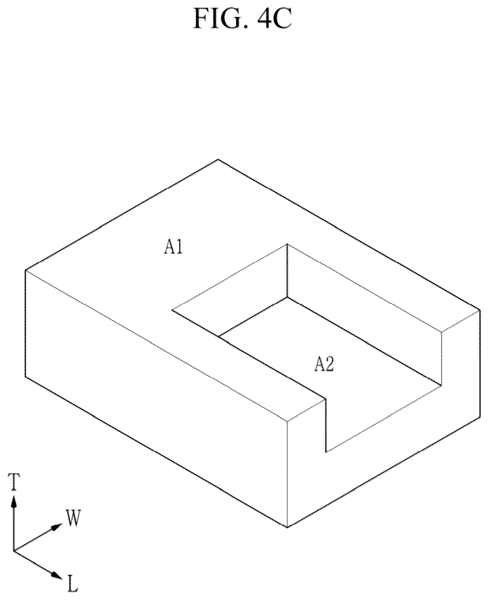

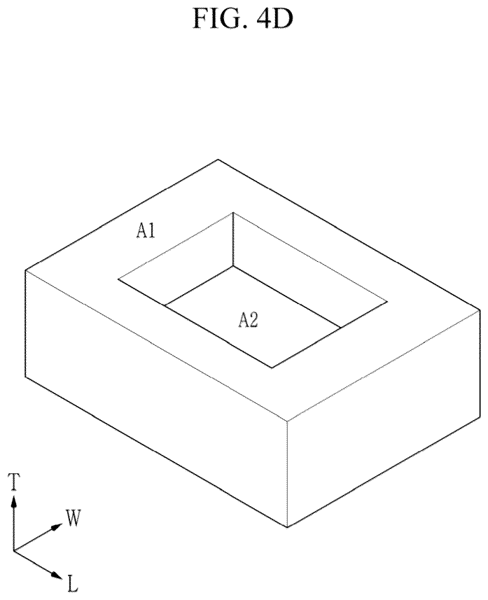

FIGS. 4A to 4D are perspective views showing an example shape of the semiconductor chip of the present disclosure.

Referring to FIG. 4A, when a direction perpendicular to a direction from the first region A1 of the first semiconductor chip 120 to the second region A2 of the first semiconductor chip 120 on a plane (e.g., in a plan view) is referred to as the width direction (W), a width of the first region A1 of the first semiconductor chip 120 and a width of the second region A2 of the first semiconductor chip 120 may be substantially the same. Here, “substantially the same” means not only being completely the same but also including an error range that may generally be recognized as being within an error range in a process or measurement. Each of the first region A1 and the second region A2 of the first semiconductor chip 120 may have a quadrilateral shape such as a rectangle, a square, or the like. A case in which widths of the first region A1 of the first semiconductor chip 120 and the second region A2 of the first semiconductor chip 120 are the same may be helpful in resisting warpage.

Referring to FIGS. 4B to 4D, at least a portion of the second region A2 of the first semiconductor chip 120 may be surrounded by the first region A1 of the first semiconductor chip 120, and the first region A1 of the first semiconductor chip 120 and the second region A2 of the first semiconductor chip 120 may have a plurality of boundary surfaces. For example, as shown in FIGS. 4B to 4D, the first region A1 of the first semiconductor chip 120 and the second region A2 of the first semiconductor chip 120 have two, three, or four boundary surfaces. The boundary surface does not necessarily have to be a surface perpendicular to a plane, but may form a specific angle (for example, an angle of about 80 degrees) with the plane. Additionally, the boundary surface does not necessarily have to be a flat surface, and may include a curved surface.

As shown in FIG. 4D, a case in which the first semiconductor chip 120 has a cavity shape where the first region A1 surrounds the second region A2 may be helpful in terms of heat dissipation and preventing warpage. In this structure, the second region A2 may include a bottom surface of the cavity, and a boundary surface between the first region A1 and the second region A2 may form a surface of a wall of the cavity.

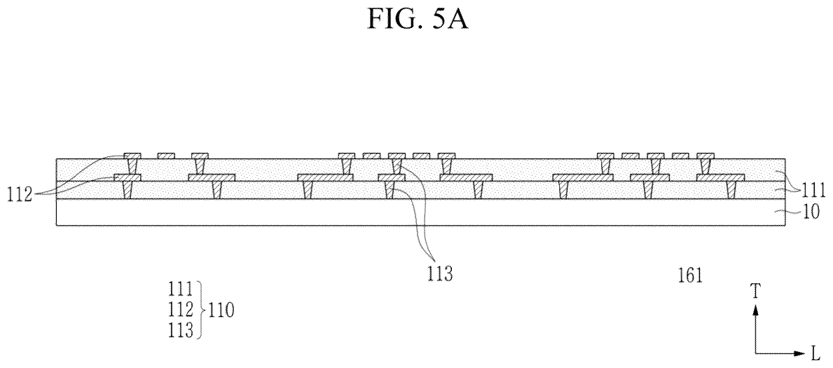

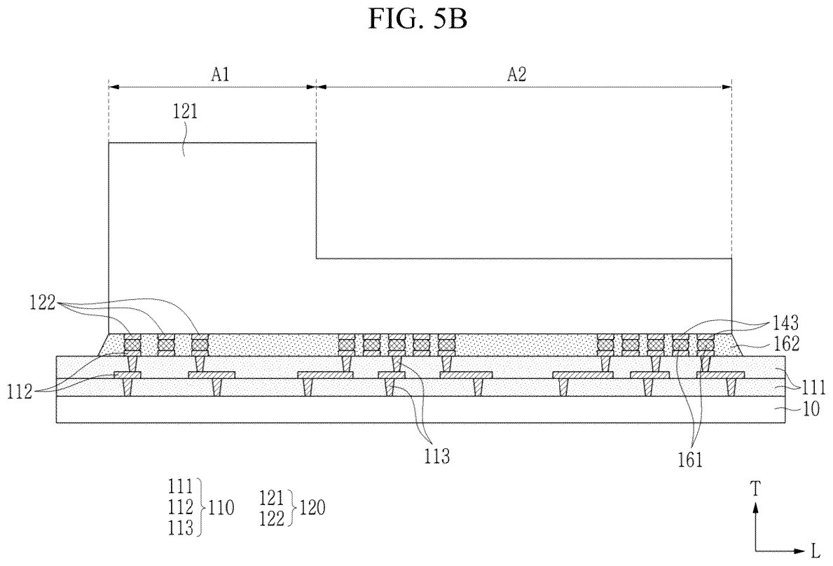

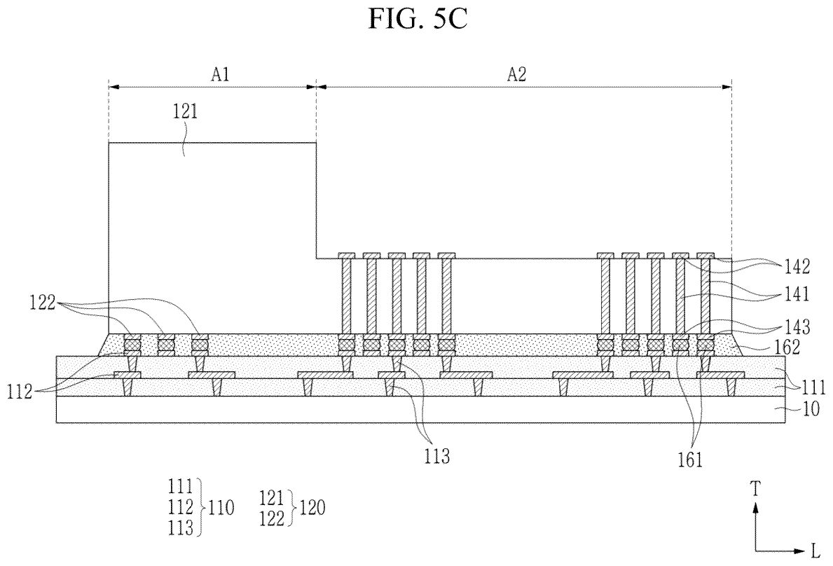

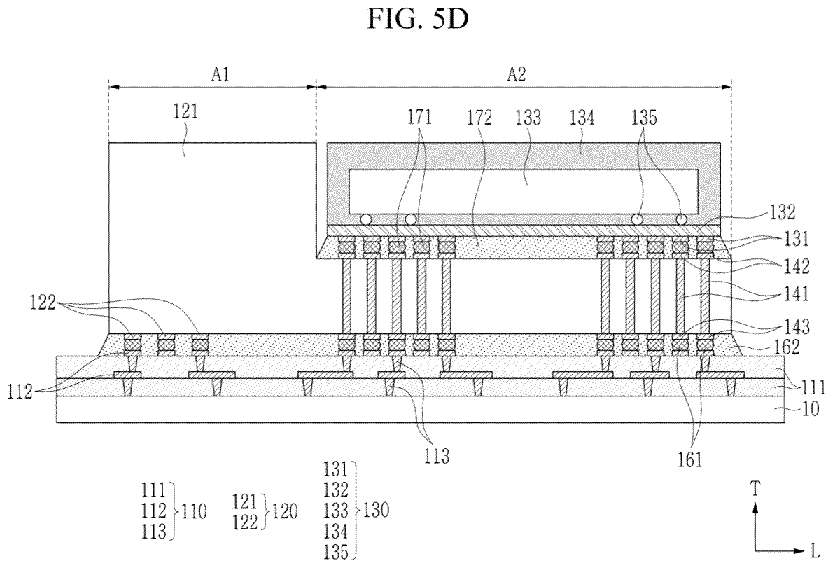

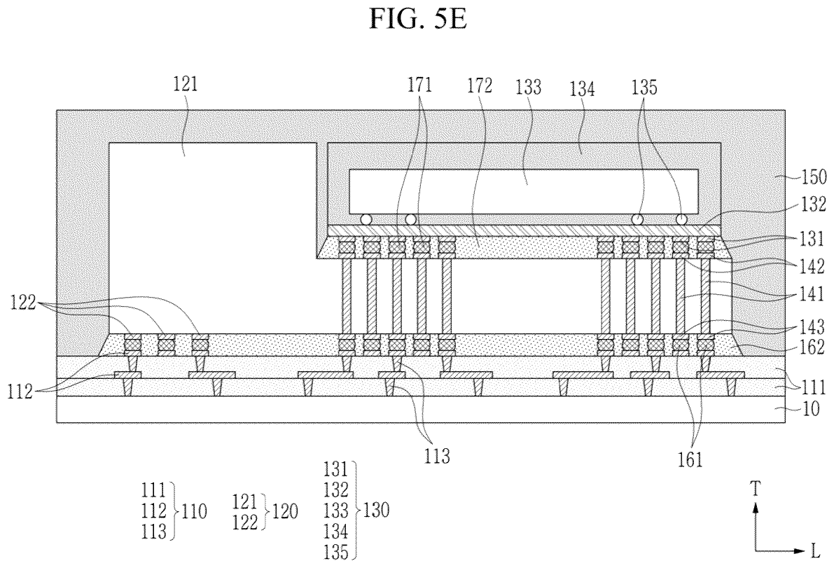

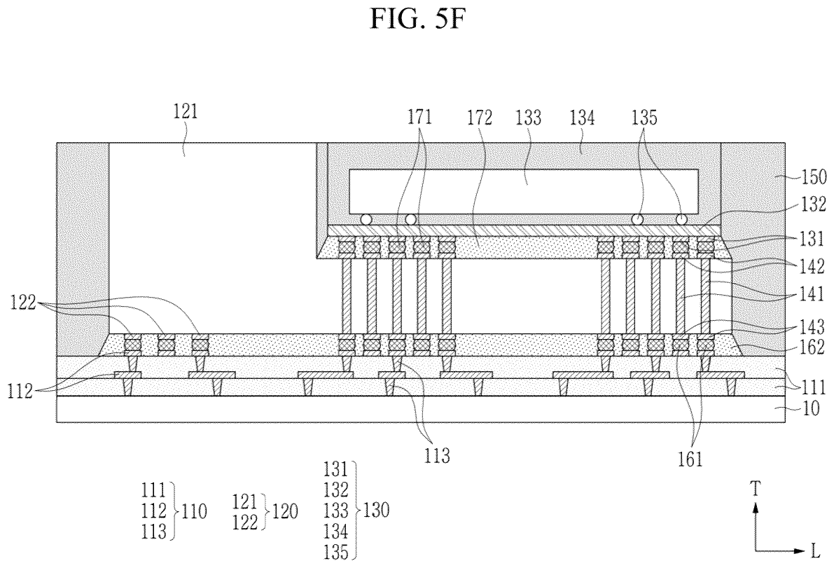

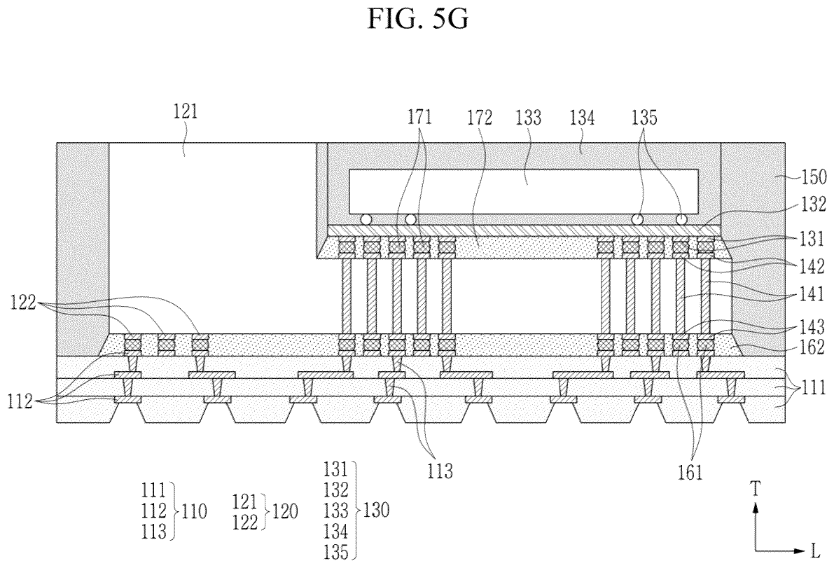

Referring to FIG. 5A to FIG. 5G, a manufacturing method of the semiconductor package 100A, according to an embodiment of the present disclosure, may include preparing the redistribution line structure 110 including the redistribution line layer 112, preparing the first semiconductor chip 120 including the first region A1 having the first thickness t1 and the second region A2 having the second thickness t2 less than the first thickness t1, disposing the first semiconductor chip 120 above or on the redistribution line structure 110, forming the silicon through via 141 penetrating the second region A2 of the first semiconductor chip 120, disposing the sub-semiconductor package 130 above the second region A2 of the first semiconductor chip 120 to connect the sub-semiconductor package 130 with the silicon through via 141, sealing the first semiconductor chip 120 and the sub-semiconductor package 130 with the second sealant 150, and grinding the second sealant 150. Description of each configuration included in the manufacturing method for the semiconductor package, according to the embodiment of the present disclosure, may be the same as that specifically described in the semiconductor package 100A, according to the embodiment of the present disclosure, so that to the extent that an element is not described in detail with respect to this figure, it may be understood that the element is at least similar to a corresponding element that has been described elsewhere within the present disclosure.

Referring to FIG. 5A, in the step of preparing the redistribution line structure 110, the redistribution line structure 110 may be prepared on a carrier film 10. For example, a process in which the first insulating layer 111 is disposed on the carrier film, the via 113 and the redistribution line layer 112 are formed above or on the carrier film, and the second insulating layer 111 is stacked on the first insulating layer 111 may be repeated to prepare the redistribution line structure 110. Some of the insulating layer 111, the redistribution line layer 112, and/or the via 113 included in the redistribution line structure 110 may be formed later, and might not be included in the redistribution line structure 110 prepared at a current step. In the present specification, the same name and symbol are used for the redistribution line structure that does not include some of the insulating layer 111, the redistribution line layer 112, and/or the via 113.

Referring to FIG. 5B, in the step of preparing the first semiconductor chip 120, the second region A2 of the first semiconductor chip 120 may have a smaller thickness than that of the first region A1 of the first semiconductor chip 120 by grinding or wet etching. When the second region A2 of the first semiconductor chip 120 is formed through the grinding process, the thickness of the second region A2 of the first semiconductor chip 120 may be more easily adjusted.

The manufacturing method for the semiconductor package, according to the embodiment of the present disclosure, may further include forming the second via pad 143. Although the present disclosure is not necessarily limited thereto, the step of forming the second via pad 143 may be performed between the step of preparing the first semiconductor chip 120 and the step of disposing the first semiconductor chip 120. For example, the seed layer may be formed on one surface of the body 121 of the first semiconductor chip 120 at which the connecting pad 122 is disposed and then the electrolytic plating layer may be formed on the seed layer so that the second via pad 143 is formed.

In the step of disposing the first semiconductor chip 120 above or on the redistribution line structure 110, the redistribution line structure 110 and the first semiconductor chip 120 may be connected to the first bump 161. For example, the redistribution line layer 112 of the redistribution line structure 110 and the connecting pad 122 of the first semiconductor chip 120 may be connected to the first bump 161. When the second via pad 143 is formed on the first semiconductor chip 120, the redistribution line structure 110 and the second via pad 143 may also be connected to the first bump 161 along with the connecting pad 122 of the first semiconductor chip 120. In this case, in order to distribute the stress applied to the first bump 161, the first underfill 162 may surround the first bump 161 between the redistribution line structure 110 and the first semiconductor chip 120.

However, the step of disposing the first semiconductor chip 120 above or on the redistribution line structure 110 may be performed by metal-metal hybrid bonding and non-metal-non-metal hybrid bonding. In this case, the connection structure between the first semiconductor chip 120 and the redistribution line structure 110 may have the structure shown in FIG. 2.

Referring to FIG. 5C, the step of forming the silicon through via 141 may include forming a through hole penetrating the body 121 at the second region A2 of the first semiconductor chip 120 and filling the through hole with a metal. For example, the step of filling the through hole with the metal may be performed through the method in which the seed layer is formed at the surface of the wall of the through hole and then the electrolytic plating layer is formed on the seed layer to fill the through hole. In this case, the through hole may expose the second via pad 143, and the metal filling the through hole may be formed on the second via pad 143 to connect the second via pad 143 to the silicon through via 141.

The manufacturing method for the semiconductor package, according to the embodiment of the present disclosure, may further include forming the first via pad 142. For example, the seed layer may be formed on the second region A2 of the body 121 of the first semiconductor chip 120 and then the electrolytic plating layer may be formed on the seed layer so that the first via pad 142 is formed. The first via pad 142 may be integrally formed with the silicon through via 141. For example, when the silicon through via 141 is formed, the seed layer may extend from the surface of the wall of the through hole onto one surface of the body 121 of the first semiconductor chip 120 and then the electrolytic plating layer may be formed on the seed layer so that the first via pad 142 is integrally formed with the silicon through via 141.

The step of forming the silicon through via 141 may be performed after the step of disposing the first semiconductor chip 120 above or on the redistribution line structure 110, but may be performed before the step of disposing the first semiconductor chip 120 above or on the redistribution line structure 110. Similarly, the step of forming the first via pad 142 may also be performed before the step of disposing the first semiconductor chip 120 above or on the redistribution line structure 110. Accordingly, the first semiconductor chip 120 may be disposed above or on the redistribution line structure 110 in a state in which the silicon through via 141 and the first via pad 142 are formed at the body 121 of the first semiconductor chip 120.

Referring to FIG. 5D, in the step of disposing the sub-semiconductor package 130 above the second region A2 of the first semiconductor chip 120 to connect the sub-semiconductor package 130 with the silicon through via 141, the sub-semiconductor package 130 and the silicon through via 141 may be connected to the second bump 171. The sub-semiconductor package 130 and the silicon through via 141 may be connected through the first via pad 142 and the second bump 171. In this case, to distribute the stress applied to the second bump 171, the second underfill 172 may surround the second bump 171 between the first semiconductor chip 120 and the substrate 132.

However, the step of disposing the sub-semiconductor package 130 above the second region A2 of the first semiconductor chip 120 to connect the sub-semiconductor package 130 with the silicon through via 141 may be performed by metal-metal hybrid bonding and non-metal-non-metal hybrid bonding. In this case, the connection structure between the first semiconductor chip 120 and the sub-semiconductor package 130 may have the structure shown in FIG. 2.

Referring to FIG. 5E, the step of sealing the first semiconductor chip 120 and the sub-semiconductor package 130 with the second sealant 150 is not necessarily particularly limited, but may be performed by compression molding or transfer molding a material such as an epoxy molding compound (EMC) or the like.

Referring to FIG. 5F, the step of grinding the second sealant 150 may reduce the thickness of the semiconductor package and increase heat dissipation characteristic of the semiconductor package. For example, the step of grinding the second sealant 150 may expose at least one of the first semiconductor chip 120 and the sub-semiconductor package 130. Particularly, the step of grinding the second sealant 150 may expose the first region A1 of the first semiconductor chip 120. Through this structure, heat generated in the semiconductor package 100A may be more efficiently dissipated to the outside of the package through the exposed surface of the first semiconductor chip 120.

Referring to FIG. 5G, the carrier film 10 may be peeled off, and if necessary, the insulating layer 111, the redistribution line layer 112, and/or the via 113 may be additionally formed. An opening exposing at least a portion of the redistribution line pattern 112p disposed at an outermost side may be formed at the insulating layer 111 that is disposed at the outermost side of the redistribution line structure 110 and includes the additionally formed insulating layer 111. The connection structure 114 may be disposed on the redistribution line pattern 112p exposed through the opening of the insulating layer 111 at the outermost side. In this case, along with the connection structure 114, a passive component such as a capacitor may be additionally disposed on the insulating layer 111 to be electrically connected to the redistribution line layer 112.

As described in the description of FIG. 3, the semiconductor package, according to the embodiment, may be formed in the chip-first method. When the chip-first method is applied, the semiconductor package may be manufactured through a method in which the first semiconductor chip 120 is disposed above the carrier film 10, the silicon through via 141 penetrating the second region A2 of the first semiconductor chip 120 is formed, the sub-semiconductor package 130 is disposed above the second region A2 of the first semiconductor chip 120 to connect the sub-semiconductor package 130 with the silicon through via 141, the first semiconductor chip 120 and the sub-semiconductor package 130 are sealed with the second sealant 150, and the carrier film 10 is peeled off and then the redistribution line structure 110 is formed after the second sealant 150 is ground. However, the order of the above-described processes may be changed depending on a design so that the changed processes are implemented.

While this disclosure has been described in connection with what is presently considered to be practical embodiments, it is to be understood that the disclosure is not necessarily limited to the disclosed embodiments, but, on the contrary, is intended to cover various modifications and equivalent arrangements included within the spirit and scope of the present disclosure.

What is claimed is:

1. A semiconductor package, comprising:
a redistribution line structure including a redistribution line layer;
a first semiconductor chip disposed above the redistribution line structure and including a first region with a first thickness and a second region with a second thickness that is less than the first thickness;
a sub-semiconductor package including a second semiconductor chip, the sub-semiconductor package being disposed above the second region of the first semiconductor chip;
a silicon through via penetrating the second region of the first semiconductor chip, and the silicon through via electrically connecting the sub-semiconductor package with the redistribution line structure; and
a sealant that seals at least a portion of each of the first semiconductor chip and the sub-semiconductor package,
wherein the sub-semiconductor package is disposed within the second region of the first semiconductor chip.

2. The semiconductor package of claim 1, wherein the first semiconductor chip and the sub-semiconductor package are exposed to one surface of the sealant.

3. The semiconductor package of claim 2, wherein on the one surface of the sealant, one surfaces of the first semiconductor chip, the sub-semiconductor package, and the sealant are coplanar with one another.

4. The semiconductor package of claim 1, wherein the thickness of the second region of the first semiconductor chip is within a range of from 50 μm to 400 μm.

5. The semiconductor package of claim 1, wherein the thickness of the first region of the first semiconductor chip is within a range from 500 μm to 800 μm.

6. The semiconductor package of claim 1, wherein when a direction perpendicular to a direction from the first region of the first semiconductor chip to the second region of the first semiconductor chip on a plane (e.g., in a plan view) is a width direction, a width of the first region of the first semiconductor chip and a width of the second region of the first semiconductor chip are substantially equal to one another.

7. The semiconductor package of claim 1, wherein at least a portion of the second region is surrounded by the first region, and the first region and the second region have a plurality of boundary surfaces.

8. The semiconductor package of claim 1, wherein a length of the first semiconductor chip is within a range of from 11 mm to 20 mm.

9. The semiconductor package of claim 1, wherein the first semiconductor chip includes a logic chip, and the second semiconductor chip includes a memory chip.

10. A semiconductor package, comprising:
a redistribution line structure including a redistribution line layer;
a first semiconductor chip disposed above the redistribution line structure and including a body and a connecting pad electrically connected to the redistribution line structure;
a sub-semiconductor package disposed above the first semiconductor chip and including a substrate having a wiring layer, a second semiconductor chip disposed above the substrate, and a first sealant sealing at least a portion of the second semiconductor chip;
a silicon through via penetrating the first semiconductor chip and electrically connecting the sub-semiconductor package to the redistribution line structure; and
a second sealant sealing at least a portion of each of the first semiconductor chip and the sub-semiconductor package,
wherein the first semiconductor chip includes a first region with a first thickness and a second region with a second thickness that is less than the first thickness, the first region of the first semiconductor chip is exposed to one surface of the second sealant, the sub-semiconductor package is disposed above the second region of the first semiconductor chip, and the silicon through via penetrates the second region of the first semiconductor chip.

11. The semiconductor package of claim 10, wherein the sub-semiconductor package is exposed to the one surface of the second sealant to which the first semiconductor chip is exposed.

12. The semiconductor package of claim 10, further comprising a first via pad and a second via pad that are respectively disposed on both surfaces of the body of the first semiconductor chip and are electrically connected to each other by the silicon through via.

13. The semiconductor package of claim 12, further comprising a bump disposed above the first semiconductor chip and electrically connecting the first via pad to the substrate.

14. The semiconductor package of claim 12, further comprising a bump disposed on the redistribution line structure and connecting at least one of the connecting pad and the second via pad to the redistribution line structure.

15. The semiconductor package of claim 12, wherein the first via pad directly contacts at least one wiring pattern included in the wiring layer of the substrate.

16. The semiconductor package of claim 12, wherein at least one of the connecting pad and the second via pad directly contacts at least one redistribution line pattern included in the redistribution line layer.

17. A manufacturing method for a semiconductor package, comprising:
preparing a redistribution line structure including a redistribution line layer;
preparing a first semiconductor chip including a first region with a first thickness and a second region with a second thickness that is less than the first thickness;
disposing the first semiconductor chip above the redistribution line structure;
forming a silicon through via penetrating the second region of the first semiconductor chip;
disposing a sub-semiconductor package above the second region of the first semiconductor chip, and electrically connecting the sub-semiconductor package with the silicon through via;
sealing the first semiconductor chip and the sub-semiconductor package with a sealant; and
grinding the sealant.

18. The manufacturing method of claim 17, wherein the grinding of the sealant exposes the first region of the first semiconductor chip.

19. The manufacturing method of claim 17, wherein in the preparing of the first semiconductor chip, the second region of the first semiconductor chip has a smaller thickness than that of the first region of the first semiconductor chip as a result of a grinding or a wet etching.

20. The manufacturing method of claim 17, further comprising forming a via pad on one surface of a body of the first semiconductor chip,
wherein the forming of the silicon through via comprises:
forming a through hole penetrating the body to expose the via pad; and
filling the through hole with a metal.
